(19) United States
(12) Patent Application Publication
(10) Pub. No.: US 2025/0155394 A1
(43) Pub. Date: May 15, 2025

(54) DETERIORATION DISCRIMINATING DEVICE AND DETERIORATION DISCRIMINATING METHOD

(71) Applicant: Mitsubishi Electric Corporation, Chiyoda-ku, Tokyo (JP)

(72) Inventor: Kazuto MINAGAWA, Chiyoda-ku, Tokyo (JP)

(73) Assignee: Mitsubishi Electric Corporation, Chiyoda-ku, Tokyo (JP)

(21) Appl. No.: 18/840,671

(22) PCT Filed: Apr. 7, 2022
(86) PCT No.: PCT/JP2022/017236

§ 371 Date: Aug. 22, 2024

(51) Int. Cl. G01N 25/72; G01R 31/34

(52) U.S. Cl. CPC G01N 25/72; G01R 31/34

(57) ABSTRACT

A deterioration determining device includes a temperature acquirer, a damage level determiner, and a determiner. The temperature acquirer acquires a temperature of an insulating member covering a conductor. The damage level determiner determines, for each target period, a damage level based on the temperature of the insulating member and on a relationship between the temperature and a service life of the insulating member. The service life is a time period for which the insulating member is usable. The damage level indicates an elapsed time within the service life corresponding to the temperature of the insulating member. The determiner determines a degree of deterioration of the insulating member based on the damage level determined for each target period.

### TECHNICAL FIELD

The present disclosure relates to a deterioration determining device and a deterioration determining method.

### BACKGROUND ART

An electric motor includes a rotor including a rotor core and rotor conductors placed in slots in the rotor core or permanent magnets, and a stator including a stator core and stator coils placed in slots in the stator core. The electric motor further includes an insulating member that insulates the stator core from the stator coils. A deteriorating insulating member may cause, for example, a short circuit inside the electric motor or a ground fault to the outside of the electric motor. The insulating member is thus preferably checked regularly for the degree of deterioration.

The electric motor mounted on a railway vehicle is large and is installed on a bogie supporting the vehicle body. This complicates maintenance including, for example, removing the electric motor from the bogie and disassembling the electric motor. Thus, the degree of deterioration of the insulating member cannot be easily checked by frequently removing the electric motor from the bogie and the insulating member from the electric motor. The degree of deterioration of the insulating member is thus preferably determined without removing the electric motor from the bogie and disassembling the electric motor. Patent Literature 1 describes an example device that determines the degree of deterioration of the insulating member.

### CITATION LIST

### Patent Literature

Patent Literature 1: Unexamined Japanese Patent Application Publication No. 2014-25753

### SUMMARY OF INVENTION

### Technical Problem

A deterioration diagnostic device described in Patent Literature 1 measures the temperature of the coils in the electric motor and converts the operation time of the electric motor at the measured actual temperature to the operation time of the electric motor at a reference temperature. More specifically, the slope of an Arrhenius plot at the actual temperature is used as the same slope as the Arrhenius plot at the reference temperature to convert the operation time of the electric motor at the actual temperature to the operation time of the electric motor at the reference temperature. The deterioration diagnostic device determines whether the coils have insulation deterioration based on comparison between an integrated value of the converted operation time and the service life span of the coils at the reference temperature.

When activation energy in an Arrhenius equation representing the relationship between the temperature and the service life of the insulating member changes with temperature, the slope of the Arrhenius plot varies at different temperatures. When the slope of the Arrhenius plot changes with temperature, a greater error may occur in converting the operation time, reducing the accuracy of deterioration diagnosis performed by the deterioration diagnostic device described in Patent Literature 1. The same applies to determining the degrees of deterioration of insulating members covering various conductors, in addition to the insulating member included in the electric motor.

Under such circumstances, an objective of the present disclosure is to provide a deterioration determining device and a deterioration determining method that can accurately determine the degree of deterioration of an insulating member covering a conductor.

### Solution to Problem

To achieve the above objective, a deterioration determining device according to an aspect of the present disclosure includes a temperature acquirer, a damage level determiner, and a determiner. The temperature acquirer acquires a temperature of an insulating member covering a conductor. The damage level determiner determines, for each target period, a damage level based on the temperature of the insulating member acquired by the temperature acquirer and on a relationship between a temperature and a service life of the insulating member. The service life is a time period for which the insulating member is usable. The damage level indicates an elapsed time within the service life corresponding to the temperature of the insulating member acquired by the temperature acquirer. The determiner determines a degree of deterioration of the insulating member based on the damage level determined for each target period.

### Advantageous Effects of Invention

The deterioration determining device according to the above aspect of the present disclosure can accurately determine the degree of deterioration of the insulating member by determining the degree of deterioration of the insulating member based on the damage level indicating the elapsed time within the service life corresponding to the temperature of the insulating member.

### BRIEF DESCRIPTION OF DRAWINGS

FIG. 1 is a block diagram of a deterioration determining device according to Embodiment 1;

FIG. 2 illustrates a hardware configuration of the deterioration determining device according to Embodiment 1;

FIG. 3 is a flowchart of an example operation of deterioration degree determination performed by the deterioration determining device according to Embodiment 1;

FIG. 4 is illustrates an example relationship between the temperature and the service life of an insulating member in Embodiment 1;

FIG. 5 is a block diagram of a deterioration determining device according to Embodiment 2;

FIG. 6 is a flowchart of an example operation of deterioration degree determination performed by the deterioration determining device according to Embodiment 2;

FIG. 7 is a block diagram of a deterioration determining device according to a first modification of the embodiment;

FIG. 8 is a flowchart of another example operation of deterioration degree determination performed by the deterioration determining device according to the embodiment.

FIG. 9 is a block diagram of a deterioration determining device according to a second modification of the embodiment; and

FIG. 10 illustrates a hardware configuration of a deterioration determining device according to a modification of the embodiment.

### DESCRIPTION OF EMBODIMENTS

A deterioration determining device and a deterioration determining method according to embodiments of the present disclosure are described in detail below with reference to the drawings. Components identical or corresponding to each other are provided with the same reference sign in the drawings.

### Embodiment 1

An example of a device including an insulating member covering a conductor is an electric motor mounted on a railway vehicle and drivable with power to generate propulsion for the railway vehicle. A deterioration determining device to determine the degree of deterioration of the insulating member included in the electric motor is described in Embodiment 1. Determining the degree of deterioration of the insulating member includes determining whether the insulating member has reached the end of the service life or not, and determining whether the insulating member is approaching the end of the service life or not.

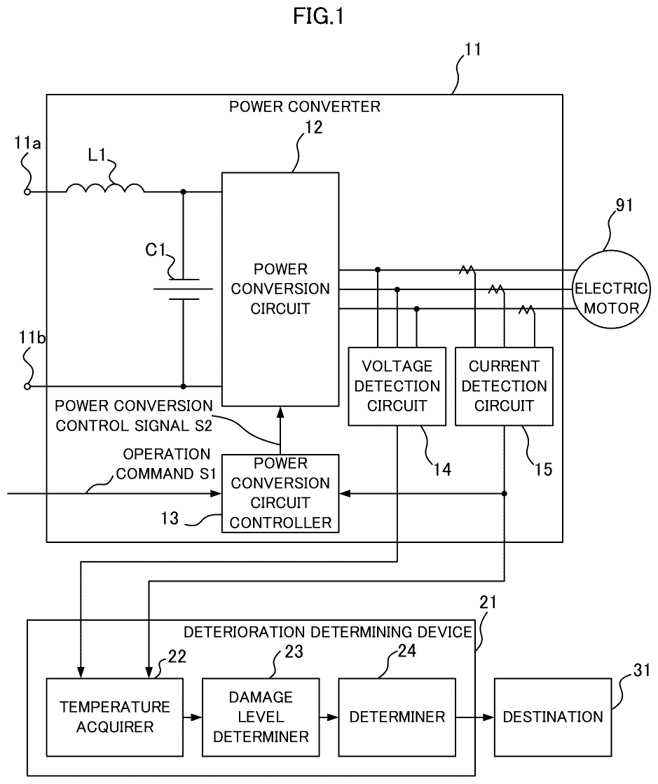

As illustrated in FIG. 1, an electric motor 91 as a target of deterioration determination is, for example, a three-phase induction motor drivable with three-phase alternating current (AC) power from a power converter 11 to generate propulsion for a railway vehicle.

Although the detailed structure of the electric motor 91 is not illustrated, the electric motor 91 includes a shaft supported in a rotatable manner, a rotor including a rotor core and rotor conductors placed in slots in the outer circumferential surface of the rotor core or permanent magnets, and a stator including a stator core and stator coils placed in slots in the inner circumferential surface of the stator core. The electric motor 91 further includes an insulating member covering the stator coils that are conductors. The insulating member insulates the stator core from the stator coils and insulates the adjacent stator coils from one another. The stator is impregnated with insulating varnish as an example insulating member to cover the stator coils with the insulating member.

The electric motor 91 is installed on a bogie supporting the vehicle body of the railway vehicle. When the electric motor 91 operates on power from the power converter 11, the shaft of the electric motor 91 rotates, and the rotational force of the shaft is transmitted to an axle through a coupling and a gear device. As the axle rotates, wheels attached to both ends of the axle rotate to generate the propulsion for the railway vehicle.

The power converter 11 that supplies power to the electric motor 91 is, for example, a direct current (DC)-three-phase converter mounted on the railway vehicle using a DC feeder to convert DC power supplied from a power source to three-phase AC power and supply the three-phase AC power to a load. The power converter 11 includes an input terminal 11a connected to the power source and an input terminal 11b grounded. The power converter 11 further includes a power conversion circuit 12 that converts DC power supplied from the power source to three-phase AC power and supplies the three-phase AC power to the electric motor 91, a power conversion circuit controller 13 that controls the power conversion circuit 12, a voltage detection circuit 14 that measures phase voltages output from the power conversion circuit 12, and a current detection circuit 15 that measures phase currents output from the power conversion circuit 12. The power converter 11 further includes a reactor L1 and a capacitor C1 connected in series between the input terminals 11a and 11b. The power converter 11 with the above structure is installed under the floor of the vehicle body of the railway vehicle.

The input terminal 11a is electrically connected through a device such as a contactor or a breaker that is not illustrated to the power source, more specifically, to a current collector that receives power supplied from an electrical substation through a power line. For example, the current collector is a pantograph that receives power through an overhead line being an example power line, or a current collector shoe that receives power through a third rail being an example power line. The input terminal 11b is grounded through, for example, a ground ring, a ground brush, or a wheel that is not illustrated.

The power conversion circuit 12 includes, for example, an inverter that outputs AC power with variable effective voltage and frequency. The power conversion circuit 12 includes multiple switching elements. The switching operations of the switching elements are controlled by the power conversion circuit controller 13. Each switching element includes, for example, an insulated-gate bipolar transistor (IGBT) or a wide bandgap semiconductor formed from, for example, silicon carbide (SiC), gallium nitride (GaN), or diamond.

The power conversion circuit controller 13 receives an operation command S1 from a driver's cab that is not illustrated. The operation command S1 is a command corresponding to an operation performed by an operator on a master controller installed in the driver's cab. More specifically, the operation command S1 is any of a powering command for accelerating the railway vehicle, a braking command for decelerating the railway vehicle, or a coasting command for coasting the railway vehicle. The coasting command indicates a state with neither the powering command nor the braking command being input. The power conversion circuit controller 13 generates and outputs power conversion control signals S2 that control the switching elements in the power conversion circuit 12 based on the operation command S1. Each of the power conversion control signals S2 is, for example, a pulse-width modulation (PWM) signal.

The voltage detection circuit 14 includes a voltage transformer (VT) electrically connected to a busbar that electrically connects the power conversion circuit 12 and the electric motor 91, and measures phase voltages output from the power conversion circuit 12, more specifically, the values of U-, V-, and W-phase voltages. The voltage detection circuit 14 transmits the measurement values of the phase voltages to the deterioration determining device 21.

The current detection circuit 15 includes an electric circuit between the power conversion circuit 12 and the electric motor 91, or for example, a current transformer (CT) attached to the busbar that electrically connects the power conversion circuit 12 and the electric motor 91, and measures phase currents output from the power conversion circuit 12, more specifically, the values of U-, V-, and W-phase currents. The current detection circuit transmits the measurement values of the phase currents to the power conversion circuit 15 controller 13 and the deterioration determining device 21.

The reactor L1 has one end connected to the input terminal 11a. The reactor L1 has the other end connected to a primary terminal of the power conversion circuit 12. The capacitor C1 has one end connected to the connecting point between the other end of the reactor L1 and the primary terminal of the power conversion circuit 12. The capacitor C1 has the other end connected to the connecting point between the input terminal 11b and the primary terminal of the power conversion circuit 12. The reactor L1 and the capacitor C1 form an LC filter that reduces harmonic components generated by the switching operations in the power conversion circuit 12.

The deterioration determining device 21 that determines the degree of deterioration of the insulating member included in the electric motor 91 described above includes a temperature acquirer 22 that acquires the temperature of the insulating member covering the stator coils included in the electric motor 91, a damage level determiner 23 that determines a damage level as an indicator of an elapsed time within the service life of the insulating member corresponding to the temperature, and a determiner 24 that determines the degree of deterioration of the insulating member based on the damage level. The deterioration determining device 21 is installed at any position on the railway vehicle, such as under the floor of the vehicle body.

The deterioration determining device 21 with the above structure determines the degree of deterioration of the insulating member for each target period that is defined as appropriate, and transmits the determination result about the degree of deterioration of the insulating member to a destination 31. The target period is sufficiently shorter than the thermal time constant of the conductor covered with the insulating member as a target of determination performed by the deterioration determining device 21, and is, for example, 1 to 5 seconds inclusive. More specifically, the deterioration determining device 21 determines the degree of deterioration of the insulating member for each target period after the first use of the conductor. The destination 31 is, for example, a display installed in the driver's cab.

The temperature acquirer 22 estimates a resistance value of the conductor from the current flowing through the conductor and from the potential of the conductor, estimates the temperature of the conductor from the estimated resistance value, and uses the estimated temperature of the conductor as the temperature of the insulating member. In Embodiment 1, the temperature acquirer 22 calculates the coil resistance value of the stator coils that are conductors, based on the measurement values of the phase voltages received from the voltage detection circuit 14 and the measurement values of the phase currents received from the current detection circuit 15. The coil resistance value positively correlates with the temperature of the stator coils. The temperature acquirer 22 thus estimates the temperature of the stator coils from the calculated coil resistance value.

The stator coils generate heat when energized. The heat is transmitted to and warms the insulating member covering the stator coils to the substantially same temperature as the stator coils. The stator coils and the insulating member thus have substantially the same temperature. The temperature acquirer 22 outputs the estimated temperature of the stator coils to the damage level determiner 23 as the temperature of the insulating member.

The damage level determiner 23 determines, for each target period, the damage level based on the temperature of the insulating member received from the temperature acquirer 22 and on the relationship between the temperature and the service life of the insulating member. The damage level indicates an elapsed time within the service life corresponding to the temperature of the insulating member. The service life is a time period for which the insulating member is usable. The service life changes in accordance with the temperature of the insulating member. More specifically, the temperature and the service life of the insulating member have the relationship of the service life being shorter for the temperature being higher. The relationship between a service life LT and a temperature T (in K) of the insulating member is expressed by the Arrhenius equation in Formula 1 below. In Formula 1 below, A is the frequency factor, Ea is the activation energy, and R is the gas constant.

$$LT = A \cdot exp ( \frac{Ea}{R \cdot T} ) \qquad ( 1 )$$

In Embodiment 1, the damage level determiner 23 determines the damage level being the ratio of the target period to the service life LT corresponding to the temperature of the insulating member. More specifically, the damage level determiner 23 uses, as the damage level, a value τ/LT resulting from dividing a target period τ by the service life LT. The damage level determiner 23 outputs, as the damage level, the value τ/LT resulting from dividing the target period τ by the service life LT to the determiner 24.

The determiner 24 determines the degree of deterioration of the insulating member based on the damage level determined in each target period τ after the first use of the conductor. More specifically, in a determination period starting at the first use of the conductor and including multiple target periods τt, the determiner 24 determines the degree of deterioration of the insulating member based on the damage level determined in each target period t. In Embodiment 1, the determiner 24 determines the degree of deterioration of the insulating member based on a cumulative damage level being a cumulative value of the damage levels in the determination period. For example, the determiner 24 calculates the cumulative damage level in the determination period and determines whether the cumulative damage level has reached a threshold or not. When the cumulative damage level in the determination period reaches the threshold, the insulating member can be determined as having reached the end of the service life. According to Miner's rule, when the cumulative damage level of a member reaches 1, the member can be determined as having reached the end of the service life. The determiner 24 thus sets the threshold to 1 and determines whether the cumulative damage level in the determination period has reached the threshold or not. The determiner 24 stores the cumulative damage level into a storage that is not illustrated and transmits the determination result to the destination 31.

The determination period starts at the first use of the conductor, such as when the railway vehicle on which the electric motor 91 is mounted starts the first operation, and lasts until maintenance of the insulating member in the electric motor 91 is performed, more specifically, until the stator is impregnated with insulating varnish again. The cumulative damage level stored in the storage is reset when the maintenance of the insulating member in the electric motor 91 described above is performed.

The destination 31 that acquires the determination result from the deterioration determining device 21 with the above structure includes, for example, a display installed in the driver's cab. Upon acquiring, from the deterioration determining device 21, the determination result indicating that the insulating member has reached the end of the service life, the display displays the acquired determination result on a screen.

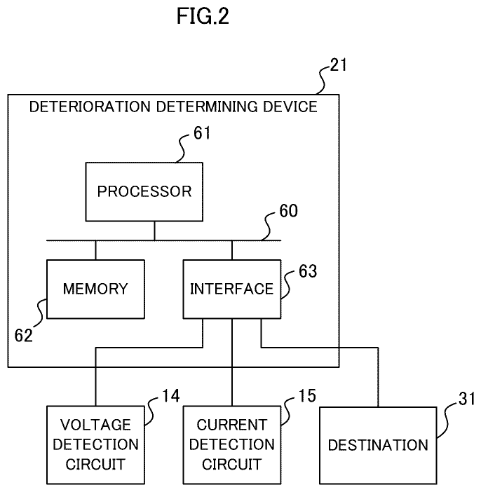

FIG. 2 illustrates the hardware configuration of the deterioration determining device 21 with the above structure. The deterioration determining device 21 includes a processor 61, a memory 62, and an interface 63. The processor 61, the memory 62, and the interface 63 are connected to one another with a bus 60. The function of each part of the deterioration determining device 21 is implemented by software, firmware, or a combination of software and firmware. The software and the firmware are described as programs and are stored in the memory 62. The processor 61 reads and executes the programs stored in the memory 62 to implement the function of each part described above. In other words, the memory 62 stores programs for executing the processing of each part of the deterioration determining device 21.

The memory 62 is, for example, a nonvolatile or volatile semiconductor memory such as a random-access memory (RAM), a read-only memory (ROM), a flash memory, an erasable programmable ROM (EPROM), or an electrically erasable programmable ROM (EEPROM), a magnetic disk, a flexible disk, an optical disc, a compact disc, a minidisc, a digital versatile disc (DVD), or another memory.

The deterioration determining device 21 is connected to, for example, the voltage detection circuit 14, the current detection circuit 15, and the destination 31 through the interface 63. The interface 63 includes an interface module compliant with one or more standards as appropriate for a connection destination.

The power converter 11 described above operates as described below.

When the operation command S1 includes the powering command, the power converter 11 in FIG. 1 converts DC power supplied from the power source to three-phase AC power and supplies the three-phase AC power to the electric motor 91. The electric motor 91 is drivable with the three-phase AC power and generates the propulsion for the railway vehicle.

More specifically, when the operation command S1 includes the powering command, the power conversion circuit controller 13 determines a torque command value τ* that is a target value of torque of the electric motor 91 in accordance with a target value of acceleration of the railway vehicle indicated by the powering command and the measurement value of the rotational speed of the electric motor 91 received from a speed sensor that is not illustrated. The power conversion circuit controller 13 determines an excitation current command value id* and a torque current command value iq* in accordance with the torque command value τ*. The power conversion circuit controller 13 determines an excitation current value id and a torque current value iq by converting the measurement values of the phase currents received from the current detection circuit 15 from three-phase coordinates to dq rotation coordinates based on an estimated position θ estimated from the measurement value of the rotational speed of the electric motor 91.

The power conversion circuit controller 13 determines an excitation voltage command value Vd* based on the difference between the excitation current value id and the excitation current command value id*, and determines a torque voltage command value Vq* based on the difference between the torque current value iq and the torque current command value iq*. The power conversion circuit controller 13 converts the excitation voltage command value Vd* and the torque voltage command value Vq* from dq rotation coordinates to three-phase coordinates based on the estimated position θ, and determines a U-phase voltage command value Vu*, a V-phase voltage command value Vv*, and a W-phase voltage command value Vw*. The power conversion circuit controller 13 generates and outputs power conversion control signals S2 that control the switching operations of the switching elements included in the power conversion circuit 12 based on each of the U-phase voltage command value Vu*, the V-phase voltage command value Vv*, and the W-phase voltage command value Vw* and a carrier wave.

When each of the power conversion control signals S2 is supplied to a gate terminal of each switching element in the power conversion circuit 12, each switching element starts the switching operation. The power conversion circuit 12 then converts DC power to three-phase AC power and supplies the three-phase AC power to the electric motor 91.

When the operation command S1 includes the braking command, the electric motor 91 that operates as a generator supplies three-phase AC power to the power converter 11. The power converter 11 converts the three-phase AC power supplied from the electric motor 91 to DC power and supplies the DC power to, through current collectors and power lines, other railway vehicles traveling near the railway vehicle on which the power converter 11 is mounted. When the three-phase AC power generated in the electric motor 91 is supplied to and consumed in the other railway vehicles, a regenerative braking force for decelerating the railway vehicle is generated.

More specifically, when the operation command S1 includes the braking command, the power conversion circuit controller 13 acquires the measurement value of the voltage across the terminals of the capacitor C1 from a voltage sensor that is not illustrated and acquires measurement values of the phase currents flowing from the electric motor 91 to the power conversion circuit 12 from the current detection circuit 15. The power conversion circuit controller 13 determines a voltage command value indicating a target value of a voltage output from the power conversion circuit 12 in accordance with the measurement value of the voltage across the terminals of the capacitor C1 and the measurement values of the phase currents flowing from the electric motor 91 to the power conversion circuit 12.

The target value of the voltage output from the power conversion circuit 12 is, for example, a value within a target voltage range that is higher than the pantograph voltage and indicates a voltage range in which regenerative braking is usable. The power conversion circuit controller 13 generates and outputs the power conversion control signals S2 that control the switching operations of the switching elements included in the power conversion circuit 12 based on the voltage command value.

When each of the power conversion control signals S2 is supplied to the gate terminal of each switching element in the power conversion circuit 12, each switching element starts the switching operation. The power conversion circuit 12 thus converts three-phase AC power supplied from the electric motor 91 to DC power and charges the capacitor C1 with the DC power.

When the railway vehicle on which the power converter 11 is mounted is near another railway vehicle accelerating, the power generated in the electric motor 91 is supplied to and consumed in the other railway vehicle as described above. This generates the regenerative braking force for decelerating the railway vehicle.

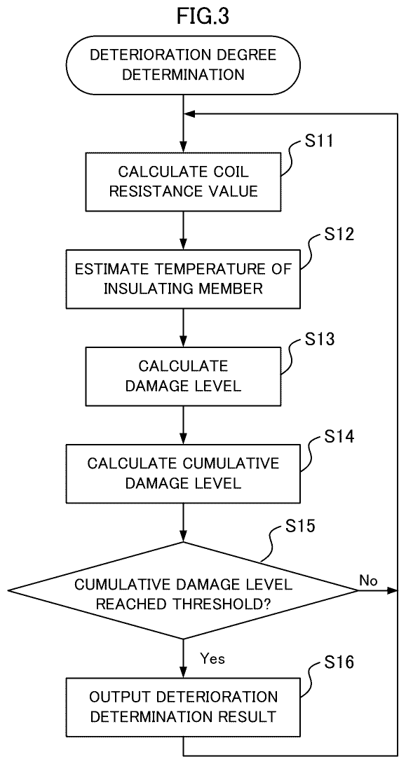

Independently of the processing by the power converter 11 described above, the deterioration determining device 21 performs determination of the degree of deterioration of the insulating member in the electric motor 91. When the railway vehicle on which the electric motor 91 is mounted starts the first operation, the deterioration determining device 21 starts determining the degree of deterioration illustrated in FIG. 3. For example, when a pantograph raising button installed in the driver's cab in the railway vehicle on which the electric motor 91 is mounted is operated to cause the railway vehicle to start the first operation, the deterioration determining device 21 starts determining the degree of deterioration illustrated in FIG. 3. The deterioration determining device 21 then continuously repeats the determination of the degree of deterioration illustrated in FIG. 3 in each target period τ=TP1 during the operation of the railway vehicle.

The temperature acquirer 22 calculates the coil resistance value of the electric motor 91 based on the measurement values of the phase voltages received from the voltage detection circuit 14 and the measurement values of the phase currents received from the current detection circuit 15 (step S11). For example, with a weak current flowing through the stator coils alone, the temperature acquirer 22 calculates a line voltage between U- and V-phases based on the measurement values of U-phase voltage and of V-phase voltage received from the voltage detection circuit 14. The temperature acquirer 22 calculates a coil resistance value Re of the U-phase stator coil using Formula 2 below based on a line voltage Vᵤᵥ between U- and V-phases and a measurement value Iᵤ of a U-phase current received from the current detection circuit 15. The temperature acquirer 22 stores the calculated coil resistance value into a storage that is not illustrated in FIG. 1.

$$Re = \frac{{V}_{uv}}{{I}_{u}} \cdot \frac{1}{2} \qquad ( 2 )$$

To calculate the coil resistance value using the above Formula 2, a current supplier preferably supplies a weak current to the stator coils alone. When the coil resistance value is calculated with a weak current from the current supplier flowing through the stator coils alone, the coil resistance value can also be calculated during coasting in which the electric motor 91 receives no power from the power converter 11.

As illustrated in FIG. 3, the temperature acquirer 22 estimates the temperature of the insulating member in the electric motor 91 from the coil resistance value calculated in step S11 (step S12). Step S12 is described in detail below.

The temperature acquirer 22 estimates the temperature of the stator coils that are conductors from the coil resistance value calculated in step S11 and the coil resistance value calculated in the last target period t. The temperature acquirer 22 stores the estimated temperature of the stator coils into the storage that is not illustrated in FIG. 1. In Embodiment 1, the temperatures of the U-, V-, and W-phase stator coils included in the same electric motor 91 change in a substantially similar manner, and the temperature of the U-phase stator coil estimated based on the coil resistance value of the U-phase stator coil calculated in step S11 is used as the temperature of the stator coils in the electric motor 91.

For example, a temperature T′ᵢ of the stator coils in an i-th target period τᵢ is calculated using Formula 3 below. In Formula 3 below, Reᵢ is a coil resistance value in the i-th target period τᵢ, Reᵢ₋₁ is a coil resistance value in a (i−1)th target period τᵢ₋₁, β is an inverse of the temperature coefficient of resistance, and T′ᵢ₋₁ is a temperature of the stator coils in the (i−1)th target period τᵢ₋₁, where i is any natural number. In the first target period τ₁ in which i=1, a temperature T₀ of the stator coils is ordinary temperature such as 20° C., and Re₀ is a coil resistance value at ordinary temperature. The temperature acquirer 22 prestores information about the temperature T′₀ of the stator coils and the coil resistance value R₀. The inverse β of the temperature coefficient of resistance is determined by a material for the conductor. For the stator coils formed from copper, for example, the value of β is 235.

$${T}_{i}^{′} = \frac{{Re}_{i}}{{Re}_{i - 1}} ( β + {T}_{i - 1}^{′} ) - β \qquad ( 3 )$$

Heat is transmitted from the stator coils to the insulating member and warm the insulating member to substantially the same temperature as the stator coils. The insulating member covering the stator coils thus have substantially the same temperature as the stator coils. The temperature acquirer 22 outputs, as the temperature Tᵢ of the insulating member, the temperature T′ᵢ of the stator coils estimated as described above to the damage level determiner 23.

As illustrated in FIG. 3, the damage level determiner 23 determines the damage level being the ratio of the target period τ to the service life LT corresponding to the temperature of the insulating member in accordance with the temperature of the insulating member estimated by the temperature acquirer 22 in step S12 (step S13). Step S13 is described in detail below.

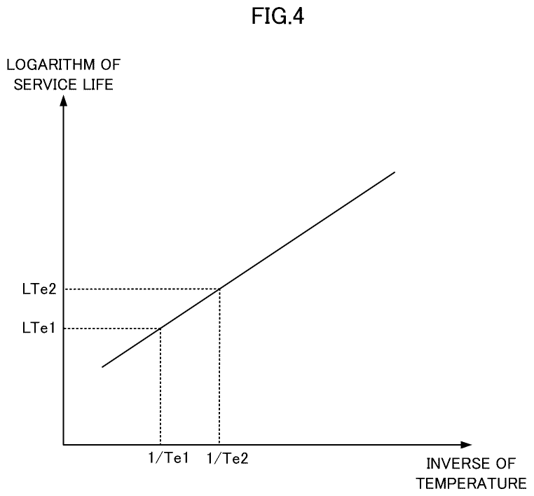

The damage level determiner 23 determines the service life LT of the insulating member in accordance with the temperature of the insulating member estimated by the temperature acquirer 22. As described above, the temperature T and the service life LT of the insulating member have the relationship of the service life LT being shorter for the temperature being higher, as expressed by the Arrhenius equation in Formula 1 above. As illustrated in FIG. 4, for example, an inverse 1/T of the temperature of the insulating member correlates positively with a logarithm log LT of the service life LT of the insulating member. The horizontal axis in FIG. 4 indicates the inverse 1/T of the temperature of the insulating member (in 1/K). The vertical axis in FIG. 4 indicates the logarithm log LT of the service life LT. In the example in FIG. 4, the inverse 1/T of the temperature of the insulating member and the logarithm log LT of the service life LT have a linear relationship. For example, the damage level determiner 23 determines a service life LTᵢ of the insulating member corresponding to the temperature Tᵢ of the insulating member in the i-th target period τᵢ based on the graph illustrated in FIG. 4.

After determining the service life LT corresponding to the temperature of the insulating member as described above, the damage level determiner 23 determines the damage level being the ratio of the target period τ to the service life LT corresponding to the temperature of the insulating member. More specifically, the damage level determiner 23 calculates a damage level Dᵢ in the i-th target period τᵢ using Formula 4 below. In Formula 4 below, τᵢ indicates the length of the i-th target period τᵢ. In Embodiment 1, τᵢ is a fixed value TP1. The damage level Dᵢ in the i-th target period τᵢ indicates the ratio of, to the service life LT of the insulating member corresponding to the temperature of the insulating member in the i-th target period τᵢ, a time elapsed within the service life LT when the i-th target period τᵢ passes. The damage level determiner 23 outputs the damage level Dᵢ calculated as described above to the determiner 24.

$${D}_{i} = \frac{{τ}_{i}}{{LT}_{i}} \qquad ( 4 )$$

The determiner 24 determines whether any deterioration of the insulating member occurs, based on the damage level Dᵢ calculated in step S13 in each target period t. More specifically, as illustrated in FIG. 3, the determiner 24 calculates the cumulative damage level (step S14). A cumulative damage level ACCᵢ from the first target period τᵢ to the i-th target period τᵢ is expressed using Formula 5 below. In Embodiment 1, τ₁=τ₂=τ₃= . . . =τᵢ=TP1 in Formula 5 below.

$${ACC}_{i} = {\sum }_{i} {D}_{i} = \frac{{τ}_{1}}{{LT}_{1}} + \frac{{τ}_{2}}{{LT}_{2}} + \frac{{τ}_{3}}{{LT}_{3}} + ⋯ + \frac{{τ}_{i}}{{LT}_{i}} \qquad ( 5 )$$

The determiner 24 determines whether the cumulative damage level ACCᵢ has reached a threshold or not (step S15). When the cumulative damage level ACCᵢ has reached the threshold (Yes in step S15), the insulating member can be determined as having reached the end of the service life. The determiner 24 thus outputs, to the destination 31, the determination result indicating that the insulating member has reached the end of the service life (step S16). When the processing in step S16 is complete, the deterioration determining device 21 repeats the processing described above from step S11.

When the cumulative damage level ACCᵢ has not reached the threshold (No in step S15), the insulating member can be determined as not having reached the end of the service life. The deterioration determining device 21 thus does not perform the processing in step S16 and repeats the processing described above from step S11.

The cumulative damage level ACC having reached 1, or in other words, the sum of the ratios of the target period τ to the service life LT of the insulating member having reached 1 indicates that the service life LT of the insulating member has passed. Thus, with the threshold being 1, the insulating member can be determined as having reached the end of the service life when the cumulative damage level ACCᵢ reaches the threshold.

For example, when the temperature is a constant temperature Te1 from the first target period τ₁ to the i-th target period τᵢ, the service life LT corresponding to the temperature Te1 is LTe1 as illustrated in FIG. 4, and thus, LT₁=LT₂=LT₃= . . . =LTᵢ=LTe1. The cumulative damage level ACCᵢ is thus expressed as i·TP1/LTe1. In other words, the cumulative damage level ACCᵢ is the ratio of the length from the first target period τᵢ to the i-th target period τᵢ to the service life LTe1. When the cumulative damage level ACCᵢ expressed as i·TP1/LTe1 reaches the threshold, the insulating member can be determined as having reached the end of the service life.

When the temperature changes between the first target period τ₁ and the i-th target period τᵢ, the cumulative damage level ACCᵢ is described as below. In one example with i=100, the temperature of the insulating member is Te1 from the first target period τᵢ to the 50th target period τ₅₀, and is Te2 in the 51st target period 151 and subsequent target periods τ. In this case, as illustrated in FIG. 4, the service life LT corresponding to the temperature Te1 is LTe1, and the service life LT corresponding to the temperature Te2 is LTe2. Thus, LT₁=LT₂=LT₃= . . . =LT₅₀=LTe1, and LT₅₁=LT₅₂= . . . =LT₁₀₀=LTe2. A cumulative damage level ACC₁₀₀ is thus expressed as 50·TP1/LTe1+50·TP1/LTe2. When the temperature of the insulating member changes as described above as well, the degree of deterioration of the insulating member can be accurately determined using the damage level Dᵢ indicating an elapsed time within the service life LT of the insulating member corresponding to the temperature.

With the threshold less than 1, such as 0.8, the insulating member can be determined as approaching the end of the service life when the cumulative damage level ACCᵢ reaches the threshold. In this case, the determiner 24 outputs, to the destination 31, the determination result indicating that the insulating member is approaching the end of the service life.

When the destination 31 acquires the determination result indicating that the insulating member has reached or is approaching the end of the service life from the deterioration determining device 21 and displays the determination result on the screen, maintenance is preferably performed, more specifically, the stator of the electric motor 91 is preferably impregnated with insulating varnish again.

As described above, the deterioration determining device 21 according to Embodiment 1 determines the degree of deterioration of the insulating member based on the damage level indicating an elapsed time within the service life LT corresponding to the temperature of the insulating member, more specifically, the damage level being the ratio of the target period τ to the service life LT corresponding to the temperature of the insulating member determined in each target period τ. This allows more accurate determination of the degree of deterioration of the insulating member covering the conductor than a deterioration determining device that converts the operation time at an actual temperature to the operation time at a reference temperature and determines, by comparing the integrated value of the converted operation time and the service life span at the reference temperature, whether any deterioration of the insulating member occurs.

### Embodiment 2

Deterioration determination performed by the deterioration determining device 21 is not limited to the above example. A deterioration determining device 21 that determines the degree of deterioration of an insulating member with processing different from the processing in Embodiment 1 is described in Embodiment 2 by focusing on the differences from Embodiment 1.

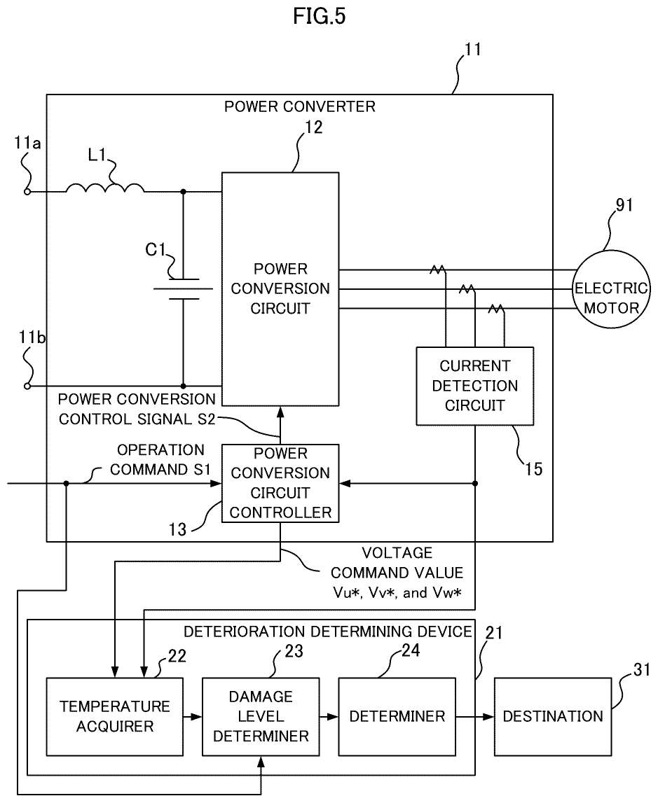

The deterioration determining device 21 illustrated in FIG. 5 includes the same components as the deterioration determining device 21 according to Embodiment 1. Unlike the deterioration determining device 21 according to Embodiment 1, the deterioration determining device 21 according to Embodiment 2 receives the operation command S1 from the driver's cab, receives the U-phase voltage command value Vu*, the V-phase voltage command value Vv*, and the W-phase voltage command value Vw* from the power conversion circuit controller 13, and receives the measurement values of the phase currents from the current detection circuit 15.

The temperature acquirer 22 calculates the resistance value of the stator coils that are conductors based on the U-phase voltage command value Vu*, the V-phase voltage command value Vv*, and the W-phase voltage command value Vw* received from the power conversion circuit controller 13 as well as the measurement values of the phase currents received from the current detection circuit 15. The temperature acquirer 22 estimates the temperature of the stator coils from the calculated coil resistance value. As in Embodiment 1, the stator coils and the insulating member covering the stator coils may have substantially the same temperature, the temperature acquirer 22 outputs the estimated temperature of the stator coils as the temperature of the insulating member.

The stator coils at different positions may have different surface areas that are exposed to the air and may thus have different temperatures. More specifically, the stator coils at some positions may have temperatures higher than the temperature of the stator coils estimated from the coil resistance value. The insulating member covering the stator coils may have portions with temperatures higher than the temperature of the insulating member output from the temperature acquirer 22. The damage level determiner 23 included in the deterioration determining device 21 according to Embodiment 2 thus performs correction to increase the temperature of the insulating member received from the temperature acquirer 22.

For example, the damage level determiner 23 multiplies the temperature of the insulating member received from the temperature acquirer 22 by a factor h1 greater than 1. The factor h1 is, for example, a value that corresponds to the maximum temperature of the stator coils when the average temperature of the stator coils is 1 based on distribution data of temperatures of the stator coils.

The damage level determiner 23 determines, in each target period τ, the damage level indicating an elapsed time within the service life LT corresponding to the temperature of the insulating member based on the temperature of the insulating member corrected as described above and on the relationship between the temperature and the service life LT of the insulating member. The damage level indicating an elapsed time within the service life LT when the target period τ passes can thus be determined as appropriate for a hot spot at which the stator coils have higher temperatures.

The damage level determiner 23 determines the damage level based on the corrected temperature of the insulating member and on the relationship between the temperature and the service life LT of the insulating member in each target period τ with a length changeable in accordance with the operation command S1. For example, the damage level determiner 23 causes a target period τ=TP2 during accelerating or decelerating, or in other words, when the operation command S1 includes the powering command or the braking command, to be shorter than a target period τ=TP3 during coasting, or in other words, when the operation command S1 includes the coasting command. The damage level determiner 23 can thus determine the service life LT corresponding to the temperature of the insulating member more frequently and can determine the damage level indicating an elapsed time within the service life LT more frequently during acceleration or deceleration in which the temperature of the stator coils in the electric motor 91 may change rapidly. Thus, the damage level indicating an elapsed time within the service life LT when the target period τ passes can be determined accurately.

The deterioration determining device 21 has the same hardware configuration as the deterioration determining device 21 according to Embodiment 1. However, unlike in Embodiment 1, the deterioration determining device 21 is connected to, for example, the current detection circuit 15, the power conversion circuit controller 13, the destination 31, and an in-vehicle device including a master controller installed in the driver's cab through the interface 63.

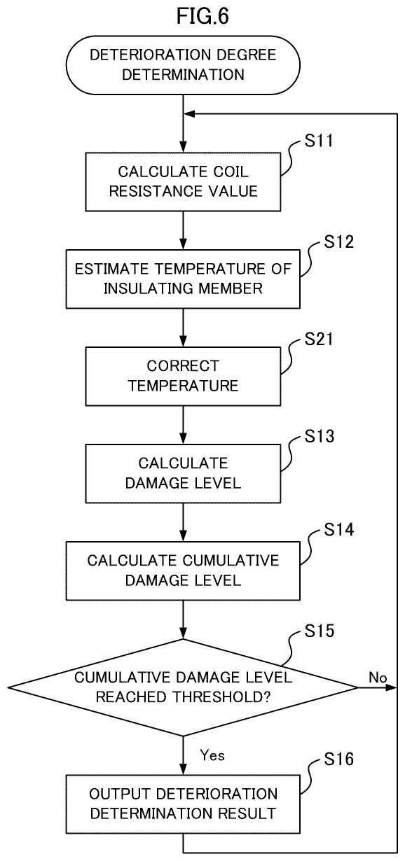

The deterioration determining device 21 with the above structure determines the degree of deterioration in the manner described below. When the railway vehicle on which the electric motor 91 is mounted starts the first operation, the deterioration determining device 21 starts determining the degree of deterioration illustrated in FIG. 6. The processing in steps S11 and S12 is the same as the processing performed by the deterioration determining device 21 illustrated in FIG. 3.

The damage level determiner 23 performs correction to increase the temperature of the insulating member estimated in step S12 (step S21). The damage level determiner 23 determines the damage level being the ratio of the target period τ to the service life LT corresponding to the temperature of the insulating member in accordance with the temperature of the insulating member corrected in step S21 (step S13). The processing in subsequent steps S14 to S16 is the same as the processing performed by the deterioration determining device 21 illustrated in FIG. 3.

As described above, the deterioration determining device 21 according to Embodiment 2 performs correction to increase the temperature of the insulating member and then determines the service life LT based on the corrected temperature of the insulating member. Thus, when the temperature varies in the insulating member, the degree of deterioration of the insulating member can be determined using a portion of the insulating member that has a higher temperature than other portions and thus has a shorter service life LT as a reference. Additionally, the deterioration determining device 21 determines the service life LT corresponding to the temperature of the insulating member more frequently during acceleration or deceleration in which the temperature of the insulating member may change rapidly than in coasting. This increases the accuracy in determining the degree of deterioration of the insulating member.

The present disclosure is not limited to the above embodiments. The hardware configuration and the flowcharts described above are examples, and may be changed or modified as appropriate.

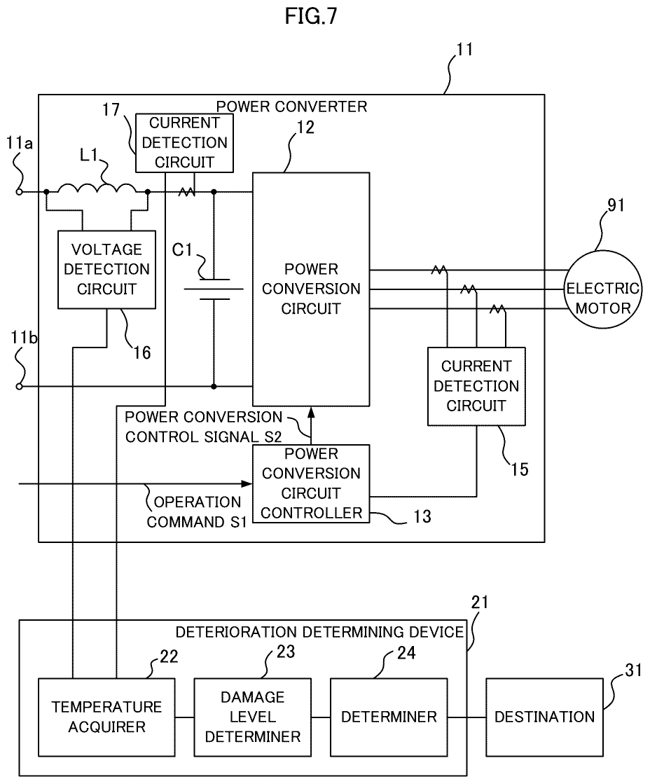

The target of determination performed by the deterioration determining device 21 is not limited to the stator coils in the electric motor 91 and is any insulating member that covers the conductor. In an example, a deterioration determining device 21 illustrated in FIG. 7 determines the degree of deterioration of an insulating member covering a conductor included in the reactor L1. The deterioration determining device 21 has the same structure as in Embodiments 1 and 2.

The power converter 11 includes a voltage detection circuit 16 that measures a voltage across the terminals of the reactor L1 and a current detection circuit 17 that measures a current flowing through the reactor L1.

The voltage detection circuit 16 is connected in parallel to the reactor L1 and measures the value of the voltage across the terminals of the reactor L1. The voltage detection circuit 16 transmits the measurement value of the voltage across the terminals to the deterioration determining device 21.

The current detection circuit 17 includes a current sensor being a Hall device attached to a busbar that electrically connects the reactor L1 and the power conversion circuit 12, and measures the value of the current flowing through the reactor L1. The current detection circuit 15 transmits the measurement value of the current to the deterioration determining device 21.

The reactor L1 includes a conductive wire and an insulating member covering the conductive wire. The conductive wire covered with the insulating member is wound to form a disk coil.

The temperature acquirer 22 calculates the coil resistance value of the disk coil included in the reactor L1 based on the measurement value of the voltage across the terminals of the reactor L1 received from the voltage detection circuit 16 and the measurement value of the current flowing through the reactor L1 received from the current detection circuit 17. More specifically, the temperature acquirer 22 divides the measurement value of the voltage across the terminals of the reactor L1 by the measurement value of the current flowing through the reactor L1 to calculate the coil resistance value. As in Embodiments 1 and 2, the temperature acquirer 22 estimates the temperature of the conductive wire of the disk coil from the calculated coil resistance value.

The conductive wire of the disk coil generates heat when energized, and the heat is transmitted to and warm the insulating member covering the conductive wire to substantially the same temperature as the conductive wire. The conductive wire of the disk coil thus has substantially the same temperature as the insulating member. The temperature acquirer 22 outputs, as the temperature of the insulating member, the estimated temperature of the disk coil to the damage level determiner 23.

With the damage level determiner 23 and the determiner 24 performing the same processing as in Embodiments 1 and 2, the degree of deterioration of the insulating member in the reactor L1 can be determined.

The temperature acquirer 22 may acquire the temperature of the insulating member with a method other than the examples described above. In an example, the temperature acquirer 22 may output a moving average value of temperatures of the insulating member acquired at different timings as the temperature of the insulating member. For example, the temperature acquirer 22 included in the deterioration determining device 21 according to Embodiment 1 estimates, in each target period τ, the temperature of the stator coils that are conductors from the measurement values of the phase voltages received from the voltage detection circuit 14 and the measurement values of the phase currents received from the current detection circuit 15.

The temperature acquirer 22 calculates the moving average value of the estimated temperatures of the stator coils and outputs the calculated moving average value to the damage level determiner 23 as a temperature Tᵢ of the insulating member. For example, in the i-th target period τᵢ, a moving average value T′_{i_avg} of temperatures of the stator coils estimated in the latest j target periods τt is expressed using Formula 6 below.

$${T}_{i \_ avg}^{′} = \frac{{T}_{i - j + 1}^{′} + {T}_{i - j + 2}^{′} + ⋯ + {T}_{i}^{′}}{j} \qquad ( 6 )$$

To reduce a deviation between the moving average value of temperatures and the actual temperature, the moving average value T′_{i_avg} of temperatures of the stator coils expressed using Formula 7 below is preferably used.

$${T}_{i \_ avg}^{′} = \frac{{T}_{i - 1}^{′} + {T}_{i}^{′}}{2} \qquad ( 7 )$$

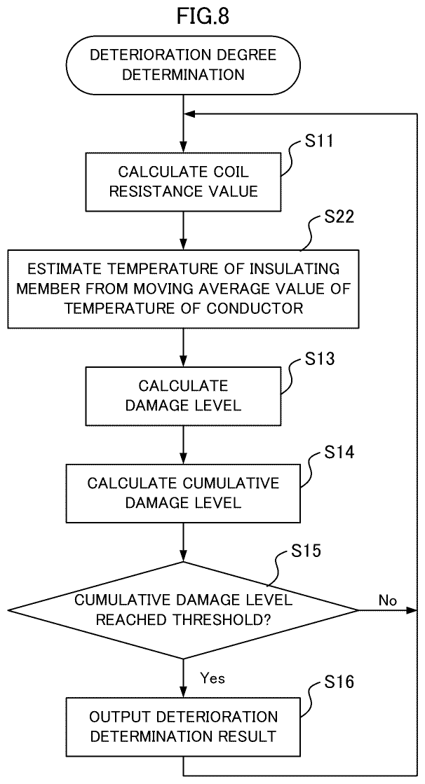

In this case, the deterioration determining device 21 starts determining the degree of deterioration illustrated in FIG. 8 when the railway vehicle on which the electric motor 91 is mounted starts the first operation. The processing in step S11 is the same as the processing performed by the deterioration determining device 21 illustrated in FIG. 3. The temperature acquirer 22 estimates the temperature of the stator coils that are conductors in the electric motor 91 from the coil resistance value calculated in step S11, calculates the moving average value of temperatures of the stator coils, and outputs, as an estimated temperature of the insulating member, the calculated moving average value to the damage level determiner 23 (step S22). The processing in subsequent steps S13 to S16 is the same as the processing performed by the deterioration determining device 21 according to Embodiment 1 illustrated in FIG. 3.

When the temperature of the conductor changes greatly, a change in the estimated temperature of the insulating member can be reduced by using the moving average value of temperatures of the conductor as the temperature of the insulating member. This suppresses great change in the damage level indicating an elapsed time within the service life LT corresponding to the temperature of the insulating member, increasing the accuracy in determining the degree of deterioration of the insulating member.

In another example, the temperature acquirer 22 may acquire, from the power conversion circuit controller 13, the U-phase voltage command value Vu*, the V-phase voltage command value Vv*, and the W-phase voltage command value Vw*, as well as a U-phase current command value, a V-phase current command value, and a W-phase current command value that are acquired by converting the excitation current command value id* and the torque current command value iq* from dq rotation coordinates to three-phase coordinates based on the estimated position θ. The temperature acquirer 22 may then calculate the coil resistance value based on the acquired command values. With the coil resistance value calculated based on the command values, the detection circuits are eliminated, reducing the computational load for computing the resistance value based on detected values.

In another example, the temperature acquirer 22 may acquire a measurement value from at least one temperature sensor that measures the temperature of the conductor to determine the temperature of the insulating member based on the measurement value of the at least one temperature sensor. More specifically, the temperature acquirer 22 may use, as the temperature of the insulating member, an average value of measurement values from multiple temperature sensors arranged in a longitudinal direction of the stator coils, or in other words, a direction in which the rotation axis of the electric motor 91 extends. The temperature sensors may be, for example, thermocouples embedded between the stator coils.

In another example, the temperature acquirer 22 may calculate the coil resistance value of each of the U-, V-, and W-phase stator coils included in the electric motor 91 and estimate the temperature of an insulating member covering the U-phase stator coil, an insulating member covering the V-phase stator coil, or an insulating member covering the W-phase stator coil from each coil resistance value. In this case, the damage level determiner 23 may determine the damage level of each insulating member covering the U-phase stator coil, the insulating member covering the V-phase stator coil, or the insulating member covering the W-phase stator coil. The determiner 24 may determine the degree of deterioration of each insulating member covering the U-phase stator coil, the insulating member covering the V-phase stator coil, or the insulating member covering the W-phase stator coil.

To determine the temperature of the insulating member more accurately, the temperature acquirer 22 may calculate the coil resistance value using an L-shaped equivalent circuit of the induction motor to estimate the temperature of the stator coils from the calculated coil resistance value. For example, a coil resistance value Reᵤ of the U-phase stator coil is expressed using Formula 8 below. In Formula 8 below, Vₚᵤ indicates the phase voltage of the U phase, ω indicates the source angular frequency, L₁ᵤ indicates a primary inductance, and L₂ indicates a secondary inductance. The number of poles in the electric motor 91 is p, and TM indicates the torque of the electric motor 91. The primary inductance L₁ᵤ and the secondary inductance L₂ may be values in a shipping test.

$${Re}_{u} = \sqrt{{( \frac{{V}_{pu}}{{I}_{u}^{′}} )}^{2} - {{ω}^{2} ( {L}_{1 u} - {L}_{2} )}^{2}} - \frac{2 ω}{3 {{pl}_{u}}^{2}} TM \qquad ( 8 )$$

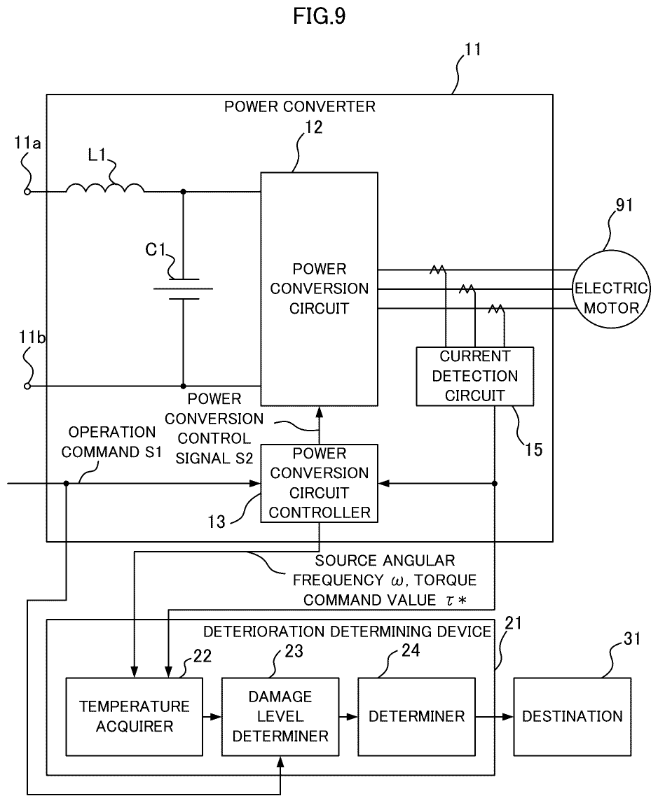

The source angular frequency ω is determined based on the excitation current command value id*, the torque current command value iq*, and the rotational speed of the electric motor 91. The temperature acquirer 22 acquires, from the power conversion circuit controller 13 as illustrated in FIG. 9, the torque command value τ* and the source angular frequency ω determined based on the excitation current command value id*, the torque current command value iq*, and the rotation speed of the electric motor 91. The temperature acquirer 22 uses the torque command value τ* as electric motor torque TM.

In Formula 8 above, Iᵤ′ is a primary conversion current and is expressed using Formula 9 below. In Formula 9 below, Iᵤ is a phase current of the U phase. In Formula 9 below, Iₘᵤ is a no-load current and is expressed using Formula 10 below. In Formula 10 below, rₘᵤ is combined excitation resistance and is expressed using Formula 11 below. In Formula 10 below, xₘᵤ is combined excitation reactance and is expressed using Formula 12 below. Impedance Z for the L-shaped equivalent circuit of the induction motor is expressed by Z=rₘᵤ+jxₘᵤ, using the imaginary unit j. In Formulas 11 and 12, Rₘ indicates iron loss resistance, and Lₘ indicates excitation inductance. The iron loss resistance Rₘ and the excitation inductance Lₘ may be values in the shipping test.

$${I}_{u}^{′} = {I}_{u} - {I}_{mu} \qquad ( 9 )$$

$${I}_{mu} = \frac{{V}_{pu}}{\sqrt{{r}_{mu}^{2} + {( {x}_{mu} )}^{2}}} \qquad ( 10 )$$

$${r}_{mu} = \frac{{ω}^{2} {R}_{m} {L}_{m}^{2}}{{R}_{m}^{2} + {( ω {L}_{m} )}^{2}} \qquad ( 11 )$$

$${x}_{mu} = \frac{{ω}^{2} {R}_{m}^{2} {L}_{m}}{{R}_{m}^{2} + {( ω {L}_{m} )}^{2}} \qquad ( 12 )$$

The temperature acquirer 22 calculates a coil resistance value Reᵥ of the V-phase stator coil and a coil resistance value Re_{w} of the W-phase stator coil in the same manner as the coil resistance value Reᵤ. The temperature acquirer 22 calculates an average coil resistance value Re_{avg} based on the coil resistance values Reᵤ, Reᵥ, and Re_{w} as in Formula 13 below.

$${Re}_{avg} = \frac{{Re}_{u} + {Re}_{v} + {Re}_{w}}{3} \qquad ( 13 )$$

The temperature acquirer 22 uses, as the coil resistance value Re, the coil resistance value Reᵤ, Reᵥ, or Re_{w} that has the greatest value when the average coil resistance value Re_{avg} is subtracted. In other words, the temperature acquirer 22 uses, as the coil resistance value Re, the coil resistance value Reᵤ, Reᵥ, or Re_{w} that has the greatest values of Reᵤ−Re_{avg}, Reᵥ−Re_{avg}, and Re_{w}−Re_{avg}. The temperature acquirer 22 estimates the temperature of the stator coils from the coil resistance value Re determined as described above.

The temperature acquirer 22 may calculate the coil resistance value using a T-shaped equivalent circuit of the induction motor to estimate the temperature of the stator coils from the calculated coil resistance value.

The temperature of the stator coils may be estimated with a method other than the examples described above. In an example, the temperature acquirer 22 may use, in Formula 3 above, the primary resistance value Re₀ measured in the shipping test in place of Reᵢ₋₁, and temperature T₀ measured in the shipping test in place of T′ᵢ₋₁. More specifically, the temperature acquirer 22 may calculate the temperature T′ᵢ of the stator coils using Formula 14 below.

$${T}_{i}^{′} = \frac{{Re}_{i}}{{Re}_{0}} ( β + {T}_{0} ) - β \qquad ( 14 )$$

The length of the target period τ is not limited to the example described above, and may change in accordance with a parameter other than the operation command S1. In an example, the length of the target period τ may change in accordance with the operating state of the device mounted on the railway vehicle. More specifically, for a railway vehicle on which multiple electric motors 91 are mounted, the length of the service life LT may change in accordance with whether at least one of the electric motors 91 has an abnormality. For example, the damage level determiner 23 may acquire information as to whether each electric motor 91 has an abnormality from an abnormality detector that detects an abnormality in the electric motors 91, and may cause a target period τ=TP4, which is the target period when at least one of the electric motors 91 has an abnormality, to be shorter than a target period τ=TP5, which is the target period when none of the electric motors 91 has an abnormality. When any of the electric motors 91 has an abnormality, other electric motors 91 without an abnormality are to increase output to cause the railway vehicle to travel at a target speed. The temperatures of the other electric motors 91 without an abnormality thus rise.

With the length of the service life LT changing in accordance with whether at least one of the electric motors 91 has an abnormality, the damage level determiner 23 can determine the service life LT corresponding to the temperature of the insulating member more frequently when the temperature of the stator coils in the electric motor 91 may increase, and can determine the damage level indicating an elapsed time within the service life LT more frequently. An elapsed time within the service life LT when the target period τ passes can thus be determined accurately.

The insulating member being the target of determination performed by the deterioration determining device 21 is not limited to varnish. In an example, the insulating member may be insulating resin, such as polyimide or polyphenylene sulfide.

The deterioration determining device 21 may be implemented as a functional component of a train information management system. The deterioration determining device 21 may not be mounted on a railway vehicle and may be installed, for example, in an operation control office.

The electric motor 91 may be either a three-phase induction motor or a three-phase synchronous motor. The electric motor 91 is not limited to a three-phase motor and may be, for example, a single-phase motor or a DC motor. The electric motor 91 may be an inner rotor or an outer rotor.

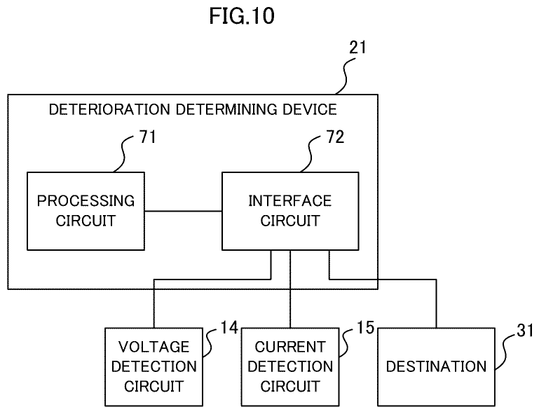

The deterioration determining device 21 may be implemented by a processing circuit 71 as illustrated in FIG. 10. The processing circuit 71 is connected to, for example, the voltage detection circuit 14, the current detection circuit 15, and the destination 31 through an interface circuit 72. When the processing circuit 71 is dedicated hardware, the processing circuit 71 is, for example, a single circuit, a complex circuit, a programmed processor, a parallel programmed processor, an application-specific integrated circuit (ASIC), a field-programmable gate array (FPGA), or a combination of two or more of these. Each part of the deterioration determining device 21 may be implemented by an individual processing circuit 71 or by a common processing circuit 71.

The deterioration determining device 21 may have some functions implemented by dedicated hardware, and other functions implemented by software or firmware. For example, the temperature acquirer 22 may be implemented by the processing circuit 71 illustrated in FIG. 10, and the damage level determiner 23 and the determiner 24 may be implemented by the processor 61 illustrated in FIG. 2 reading and executing the programs stored in the memory 62.

The foregoing describes some example embodiments for explanatory purposes. Although the foregoing discussion has presented specific embodiments, persons skilled in the art will recognize that changes may be made in form and detail without departing from the broader spirit and scope of the invention. Accordingly, the specification and drawings are to be regarded in an illustrative rather than a restrictive sense. This detailed description, therefore, is not to be taken in a limiting sense, and the scope of the invention is defined only by the included claims, along with the full range of equivalents to which such claims are entitled.

### REFERENCE SIGNS LIST

11 Power converter
11a, 11b Input terminal
12 Power conversion circuit
13 Power conversion circuit controller
14, 16 Voltage detection circuit
15, 17 Current detection circuit
21 Deterioration determining device
22 Temperature acquirer
23 Damage level determiner
24 Determiner
31 Destination
60 Bus
61 Processor
62 Memory
63 Interface
71 Processing circuit
72 Interface circuit
91 Electric motor
C1 Capacitor
L1 Reactor
S1 Operation command
S2 Power conversion control signal

1. A deterioration determining device, comprising:
temperature acquiring circuitry to acquire a temperature of an insulating member covering a conductor;
damage level determining circuitry to determine, for each target period, a damage level based on the temperature of the insulating member acquired by the temperature acquiring circuitry and on a relationship between a temperature and a service life of the insulating member, the service life being a time period for which the insulating member is usable, the damage level indicating an elapsed time within the service life corresponding to the temperature of the insulating member acquired by the temperature acquiring circuitry; and
determining circuitry to determine a degree of deterioration of the insulating member based on a cumulative damage level that is a cumulative value of the damage level determined for each target period.

2. The deterioration determining device according to claim 1, wherein
the determining circuitry determines the degree of deterioration of the insulating member based on the damage level determined for each target period after a first use of the conductor.

3. The deterioration determining device according to claim 1, wherein
the damage level determining circuitry determines the damage level being a ratio of the target period to the service life corresponding to the temperature of the insulating member acquired by the temperature acquiring circuitry.

4. The deterioration determining device according to claim 3, wherein
the target period is shorter than the thermal time constant of the conductor.

5. The deterioration determining device according to claim 1, wherein
the temperature and the service life of the insulating member have a relationship of the service life being shorter for the temperature being higher.

6. The deterioration determining device according to claim 1, wherein
the temperature acquiring circuitry acquires a temperature of the conductor and uses the acquired temperature of the conductor as the temperature of the insulating member.

7. The deterioration determining device according to claim 6, wherein
the temperature acquiring circuitry estimates a resistance value of the conductor from a current flowing through the conductor and from a potential of the conductor, estimates the temperature of the conductor from the estimated resistance value, and uses the estimated temperature of the conductor as the temperature of the insulating member.

8. The deterioration determining device according to claim 6, wherein
the temperature acquiring circuitry calculates a moving average value of temperatures of the insulating member acquired at different timings and uses the moving average value as the temperature of the insulating member.

9. The deterioration determining device according to claim 1, wherein
the damage level determining circuitry performs correction to increase the temperature of the insulating member acquired by the temperature acquiring circuitry for each target period and determines the damage level based on the temperature of the insulating member after the correction and on the relationship between the temperature and the service life of the insulating member.

10. (canceled)

11. (canceled)

12. (canceled)

13. (canceled)

14. (canceled)

15. A deterioration determining device, comprising:
temperature acquiring circuitry to acquire a temperature of an insulating member covering a conductor;
damage level determining circuitry to perform correction to increase the temperature of the insulating member acquired by the temperature acquiring circuitry for each target period, and determine, for each target period, a damage level based on the temperature of the insulating member after the correction and on a relationship between a temperature and a service life of the insulating member, the service life being a time period for which the insulating member is usable, the damage level indicating an elapsed time within the service life corresponding to the temperature of the insulating member acquired by the temperature acquiring circuitry; and
determining circuitry to determine a degree of deterioration of the insulating member based on the damage level determined for each target period.

16. The deterioration determining device according to claim 1, wherein
the temperature acquiring circuitry acquires the temperature of the insulating member covering the conductor included in a device mounted on a railway vehicle.

17. The deterioration determining device according to claim 16, wherein
the damage level determining circuitry determines the damage level for each target period with a length changeable in accordance with an operation command for the railway vehicle.

18. The deterioration determining device according to claim 17, wherein
the damage level determining circuitry determines the damage level for each target period with a length changeable in accordance with an operating state of the device.

19. The deterioration determining device according to claim 17, wherein
the temperature acquiring circuitry acquires the temperature of the insulating member covering the conductor included in each of a plurality of electric motors mounted on the railway vehicle to generate propulsion for the railway vehicle, and
the damage level determining circuitry determines the damage level for each target period with a length changeable based on whether an electric motor of the plurality of electric motors has an abnormality.

20. A deterioration determining method, comprising:
acquiring a temperature of an insulating member covering a conductor;
determining, for each target period, a damage level based on the acquired temperature of the insulating member and on a relationship between a temperature of the insulating member and a service life being a time period for which the insulating member is usable, the damage level indicating an elapsed time within the service life corresponding to the acquired temperature of the insulating member; and
determining a degree of deterioration of the insulating member based on a cumulative damage level that is a cumulative value of the damage level determined for each target period.
